(19) United States
(12) Patent Application Publication
(10) Pub. No.: US 2008/0298061 A1
(43) Pub. Date: Dec. 4, 2008

(54) Light Emitting Module and Manufacturing Method

(75) Inventors: Johannes Wilhelmus Weekamp, Eindhoven (NL); Willem Hoving, Eindhoven (NL); Eric Cornelis Egbertus Van Grunsven, Eindhoven (NL); Piet Christiaan Jozef Van Rens, Asten (NL); Gerard Maria Janssen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/094,614

(22) PCT Filed: Nov. 20, 2006
(86) PCT No.: PCT/IB06/54333

§ 371 Date: May 22, 2008

(30) Foreign Application Priority Data
Nov. 22, 2005 (EP) 05111063.3

(51) Int. Cl. F21K 7/00; G02B 27/00; H01L 21/00

(52) U.S. Cl. 362/240; 362/259; 438/26; 257/E21.001

(57) ABSTRACT

A light emitting module (19), comprising at least one semi-conductor light source (20a-c) capable of emitting light, and a light-modifying member (21) arranged adjacent to the at least one semiconductor light source (20a-c) in a direction of emission of the light. The light-modifying member (21) is formed by a stacked sheet element (21) separated from an integral stacked sheet structure comprising first and second stacked sheets, so that the stacked sheet element (21) includes first and second sheet portions of the first and second stacked sheets, and at least the first sheet portion is configured to modify the emitted light. By providing the light-modifying member as a stacked sheet element which has been separated from an integral stacked sheet structure, batch manufacturing of the light-modifying member and/or the light emitting module is enabled, such that manufacturing steps requiring manual labor, or use of expensive equipment may be performed to produce the integral stacked sheet structure. The costs for these manufacturing steps may then be distributed over a large number of components, thereby reducing manufacturing costs.

The present invention relates to a light emitting module comprising at least one semiconductor light source capable of emitting light, and a light-modifying member arranged adjacent to the at least one semiconductor light source in a direction of emission of the light, and a lighting device comprising such a light emitting module.

The invention further relates to a method for manufacturing a stacked sheet element, such as a light-modifying member or a light emitting module.

Recently, applications for compact, high intensity lamps have become more and more wide-spread and diversified. Such applications, for example, include computer and/or television-connectable projectors, which are rapidly replacing traditional presentation tools, such as over-head projectors etc.

A key component in such projectors is the lamp. It needs to be able to reliably emit high intensity light, and at the same time, in order for the projector or other application to meet mass-market requirements, be small, relatively cheap, and energy efficient.

From a performance point-of-view, a lamp based on semiconductor light sources, such as LEDs or various types of laser diodes, may in principle be superior to other, more conventional, types of light-sources, for example in that such a lamp would be robust and have a long guaranteed lifetime.

US 2005/0041000 discloses a projection type display device, in which diode lasers are used to generate light. In this display device, each diode laser is coupled via an optical fiber to beam-shaping and outcoupling optics.

The lamp assembly disclosed in the above document appears space-consuming, intricate, and not suitable for mass-production. Furthermore, extensive use of manual assembly seems unavoidable. This obviously results in a costly product.

For alleviating the above problems connected with prior art, there is thus a need for a more cost-efficient lighting device based on semiconductor light-sources. Particularly, there is a need for a semiconductor-based light emitting module, which is suitable for mass-production.

In view of the above-mentioned and other drawbacks of prior art, a general object of the present invention is to provide an improved semiconductor-based light-emitting module.

A further object of the present invention is to enable mass-production of such a light-emitting module.

According to a first aspect of the present invention, these and other objects are achieved by a light emitting module, comprising at least one semiconductor light source capable of emitting light, and a light-modifying member arranged adjacent to the at least one semiconductor light source in a direction of emission of the light, wherein the light-modifying member is formed by a stacked sheet element separated from an integral stacked sheet structure comprising first and second stacked sheets, so that the stacked sheet element includes first and second sheet portions of the first and second stacked sheets, and wherein at least the first sheet portion is configured to modify the emitted light.

In the context of the present application, “a semiconductor light source” should be understood as a light source in which at least one semiconductor material is involved in generation and/or emission of light. Such light sources, for example, include various types of light-emitting diodes (LEDs) and semiconductor lasers, such as so-called edge emitting or surface emitting lasers.

By the term “light-modifying member” should be understood a member capable of, in any way, modifying light. Light can consequently be modified by such a light-modifying member with respect to any property, including fundamental light properties, such as wavelength, wavelength distribution, and polarization, and light beam related properties, such as beam direction, beam width, beam shape, beam divergence or convergence etc. Furthermore, the light-modifying member may be capable of partially or completely blocking light.

An “integral stacked sheet structure” should be understood as a structure which has been formed by stacking and joining at least two sheets.

Stacking of sheets and dividing these to form singularized parts is known per se. For light emitting modules, however, this approach has previously not been suggested. Regarding light emitting modules intended for lighting applications in particular, the approach of the present invention, indeed, represents a completely new line of thought, which would not occur to the skilled person in this field.

It is especially advantageous that each sheet or sheet portion may carry one or more specific functionalities needed for the proper operation of the light emitting module.

It should be noted that a light-modifying member formed by a stacked sheet element which has been separated from an integral stacked sheet structure is distinguishable from a part which has been manufactured by stacking and joining pre-separated sheet portions. Such a distinction can, for example, be determined by studying a side edge of the light-modifying member, which, in the case of the light emitting module of the present invention, has a section surface resulting from only one separation process performed on the integral stacked sheet structure from which the stacked sheet element has been separated. The side edge may be studied and analyzed using a variety of tools, such as any one of an optical microscope, an electron microscope, a mechanical surface measuring device and material analysis equipment. Depending on separation method used for separating the integral stacked sheet structure, various distinguishing features may be determined. In the case of mechanical sawing, for example, a continuous sawing pattern spanning over section surfaces of several sheets may be determined. Furthermore, residues from a layer may have been dragged along the section surface of an adjacent layer and deposited there. If an alternative separation method, such as laser cutting or water jet cutting has been used, other distinguishing features may be determined. An example of such a feature in the case of laser cutting may be that traces of carbon resulting from the laser ablation process may be detected at the section surface. It should, furthermore, be noted that such an intricate analysis in most cases would not need to be performed, since the perfect sheet portion alignment inherent to the stacked sheet element separated from an integral stacked sheet structure would be readily apparent from a quick examination under an optical microscope.

By providing the light-modifying member as a stacked sheet element which has been separated from an integral stacked sheet structure, batch manufacturing of the light-modifying member and/or the light emitting module is enabled, such that manufacturing steps requiring manual labor, or use of expensive equipment may be performed to produce the integral stacked sheet structure. The costs for these manufacturing steps may then be distributed over a large number of components, thereby reducing manufacturing costs.

Furthermore, quality level and consistency of the light-emitting module may be improved compared to prior art, since a large number of light-emitting modules are influenced in essentially the same way by a certain manufacturing step, such as aligning first and second sheets of the integral stacket sheet structure from which the stacked sheet structure forming the light-modifying member is separated.

Additionally, working with sheets may enable use of production methods which are not feasible for singular parts. Such production methods may include screen printing, automated component placing, automated wire bonding, drilling, milling, molding etc. Thereby, in addition to improvements in quality and reduction in cost, more compact light emitting modules may be achieved.

By additionally configuring the second sheet portion to modify the light emitted by the semiconductor light source, a more complex modification of the emitted light may be achieved.

Advantageously, at least one of the sheet portions may contain at least one optical element.

Furthermore, the light-modifying member may preferably be arranged such that the at least one optical element is aligned with the at least one semiconductor light source.

The light emitting module may, furthermore, comprise a plurality of semiconductor light sources and at least a first corresponding plurality of optical elements contained in the at least one sheet portion.

Optical elements may be contained in one or more of the sheet portions included in the light-modifying member. For example, a first plurality of first optical elements may be contained in the first sheet portion and a second plurality of second optical elements may be contained in the second sheet portions. Each of the first optical elements may advantageously be aligned with a corresponding one of the second optical elements. This may preferably be accomplished through aligning the first and second sheets comprised in the integral stacked sheet structure.

The at least one optical element, contained in at least one of the sheet portions may be embedded in a corresponding cavity in the sheet portion.

Through the formation of cavities at suitable locations in at least one of the sheets comprised in the integral stacked sheet structure from which the light-modifying member is separated, optical elements may be accurately positioned. Furthermore, automatic placement of optical elements is facilitated, thereby improving the mass-producability of the light emitting module.

Cavities may be formed in a variety of ways, such as for example through drilling, milling, molding, punching, coining, machining, or laser ablation.

The light-modifying member comprised in the light emitting module according to the present invention may further include a third sheet portion of a third stacked sheet comprised in the integral stack structure.

Through the inclusion of a third sheet portion, a third functionality may be achieved by the light-modifying member. Such a third functionality may include modification of light emitted by the semiconductor light source, protection of optical elements included in other layers, electrically interconnecting other sheet portions and/or the semiconductor light source(s) and supporting various electrical and/or mechanical components.

Furthermore, at least one of the sheet portions included in the light-modifying member may include circuitry for enabling control of the light emitting module.

This circuitry may include passive and/or active components. Examples of functionalities achieved by this circuitry may, for example, include decoupling of the at least one semiconductor light source, heating and/or control of optical elements, sensing of light emitted by the at least one semiconductor light source, control of the semiconductor light source(s), and control of modulation of light emitted by the at least one semiconductor light source.

Hereby, a compact and more or less stand-alone light emitting module may be realized. The circuitry may, for example, be provided as electronic components which are attached to a sheet through soldering or any other connection method. To enable stacking of the sheets, the components may be received by corresponding recesses formed in an adjacent layer. Alternatively, such components may be attached to one of or both the sheets which are intended for being positioned at the top and bottom of the integral stacked sheet structure, and the components may be allowed to protrude from the sheet(s).

Advantageously, the light-modifying member may comprise connecting means for connecting the light emitting module to external control circuitry.

Such connecting means may, for example, be pins or pads adapted for various connection methods, such as soldering, pressing, welding, or glueing.

By providing connecting means on the light-modifying member, additional functionality may be achieved by this member. In addition to modifying light emitted by the at least one semiconductor light source, the light modifying member may enable connection to, and external control of the light emitting module.

The connection means may preferably be provided at a section surface, which is uncovered upon separation of the light modifying member from the integral stacked sheet structure. This may, for example, be achieved by providing a plurality of metallized holes in at least one of the sheets in the integral sheet structure. Connection means are then formed upon separation or dicing, for example through sawing, through the metallized holes. Furthermore, connection means may be formed at the top of the uppermost sheet or at the bottom of the lowest sheet.

According to one embodiment of the first aspect of the present invention, the light emitting module may comprise a first semiconductor light source capable of emitting light having a first wavelength distribution, and a second semiconductor light source capable of emitting light having a second wavelength distribution, wherein the light emitting module is capable of emitting light having a third wavelength distribution achieved through combining light emitted by at least the first and second semiconductor light sources.

By including in the light emitting module at least two semiconductor light sources capable of emitting light at different principal wavelengths, light of another wavelength may be emitted by the light emitting module. Through a proper selection of semiconductor light sources, and potentially other optical elements, such as frequency converting elements, e.g. frequency doublers and up- or down-conversion materials, light at a desired color, such as white, may be emitted by the light emitting module.

According to another embodiment of the first aspect of the present invention, the light emitting module may comprise a first semiconductor light source capable of emitting light having a first wavelength distribution, a second semiconductor light source capable of emitting light having a second wavelength distribution, a third semiconductor light source capable of emitting light having a third wavelength distribution, and a light-modifying member, including a first sheet portion having at least three cavities each containing an optical element, and a second sheet portion configured to cover the cavities in the first sheet portion, thereby protecting the optical elements, wherein each of the semiconductor light sources is arranged in a position where the particular light source is aligned to a corresponding optical element, and joined to the light-modifying member at that position.

The light emitting module according to the first aspect of the present invention may advantageously be comprised in a lighting device, further comprising control circuitry configured to control the light emitting module, and a power supply configured to supply power to the light emitting module.

According to a second aspect of the present invention, the above-mentioned and other objects are achieved by a method for manufacturing a stacked sheet element, comprising the steps of providing a first sheet configured to modify light emitted by a semiconductor light source, providing a second sheet, stacking and aligning the first and second sheets, joining the first and second sheets, thereby forming an integral stacked sheet structure, and dividing the integral stacked sheet structure, thereby forming a plurality of stacked sheet elements, each including a first sheet portion and a second sheet portion.

The first sheet may be configured to more or less homogeneously modify light, or the first sheet may contain a plurality of optical elements. Such optical elements may include variable elements, such as controllable spatial light modulators, or fixed elements, such as fixed lenses or mirrors.

Suitable materials for the sheets depend on their intended respective functionalities. For at least one of the sheets, a conventional circuit board material, such as FR-4, may be the preferred choice of material.

The sheets may be joined using any one of a variety of methods. The sheets may, for example, be joined through glueing, welding, soldering, mechanical clamping through springs or screws, or a combination of these joining methods.

The integral stacked sheet structure may be divided using any suitable method, such as, for example, through sawing, milling, water-jet, laser cutting, etc.

Advantageously, the step of providing a first sheet may comprise the steps of providing a first sheet having at least a first plurality of cavities, each of which cavities being adapted to receive a first optical element, and positioning first optical elements in corresponding cavities.

These cavities may be formed in a variety of ways, such as by drilling, milling, molding, punching, coining, machining, laser ablation etc.

According to a preferred embodiment, first strip shaped stacked sheet elements divided from a first stacked sheet structure, and second strip shaped stacked sheet elements divided from a second stacked sheet structure, are aligned and joined side-by-side, to form a compound integral stacked sheet structure. This compound structure is then divided into a plurality of compound stacked sheet elements, such that each compound stacked sheet element includes portions of both said first and second stacked sheet elements. Of course, this method is readily extendable to three or more different strips.

This embodiment of the method according to the present invention is especially useful for manufacturing stacked sheet elements for applications where light of mixed colors should be emitted. A number of stacked sheet strips may then be separated from various integral stacked sheet structures adapted for different colors. For example, three different colors, such as red, green and blue, may be combined.

By aligning and joining several sheet strips, a new compound stacked sheet structure adapted for a mixture of these first and second colors is formed. This compound stacked sheet structure may subsequently be divided so that each of the compound stacked sheet elements thus formed includes at least one portion from each of the stacked sheet strips used.

The method according to the present invention may further include the step of providing each ofthe stacked sheet elements with at least one semiconductor light source, thereby forming a plurality of light emitting modules.

According to one embodiment of the method according to the present invention, this step of providing may comprise the step of attaching a plurality of semiconductor light sources to the integral stacked sheet structure, so that at least one semiconductor light source is provided to each of the stacked sheet elements.

The above mentioned plurality of light emitting modules is thus, according to this embodiment, formed by first attaching a plurality of semiconductor light sources to the integral stacked sheet structure and subsequently dividing the integral stacked sheet structure.

According to another embodiment of the method according to the present invention, the step of providing may comprise the step of attaching at least one semiconductor light-source to each of the stacked sheet elements following division.

Further effects obtained through this second aspect of the present invention are largely analogous to those described above in connection with the first aspect of the invention.

For exemplifying purposes, these and other aspects of the present invention will now be described in more detail, with reference to the appended drawings showing currently preferred embodiments of the invention, wherein:

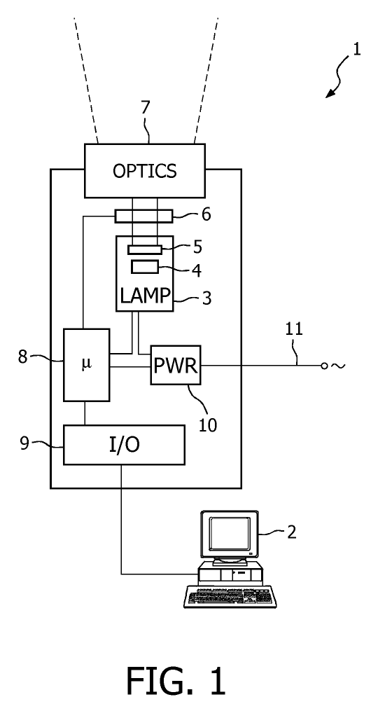

FIG. 1 is a schematic illustration of an exemplary lighting device according to the present invention.

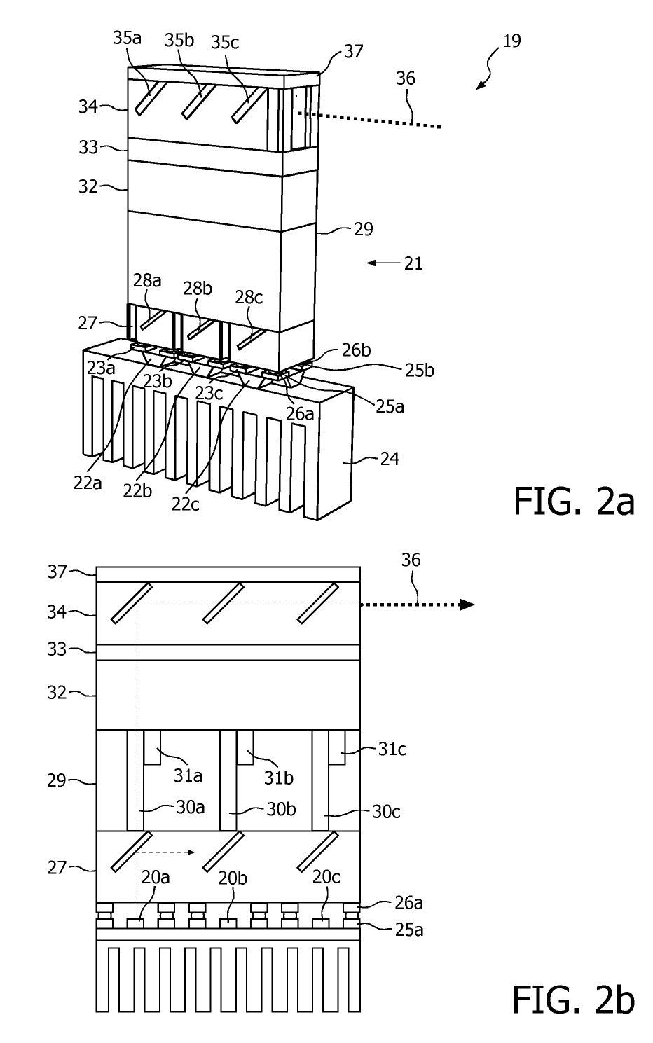

FIG. 2a is a perspective view of preferred embodiment of a light emitting module according to the present invention.

FIG. 2b is a section view ofthe light emitting module in FIG. 2a.

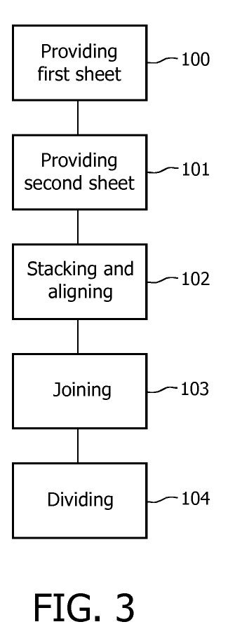

FIG. 3 is a flow chart illustrating a manufacturing method according to the present invention.

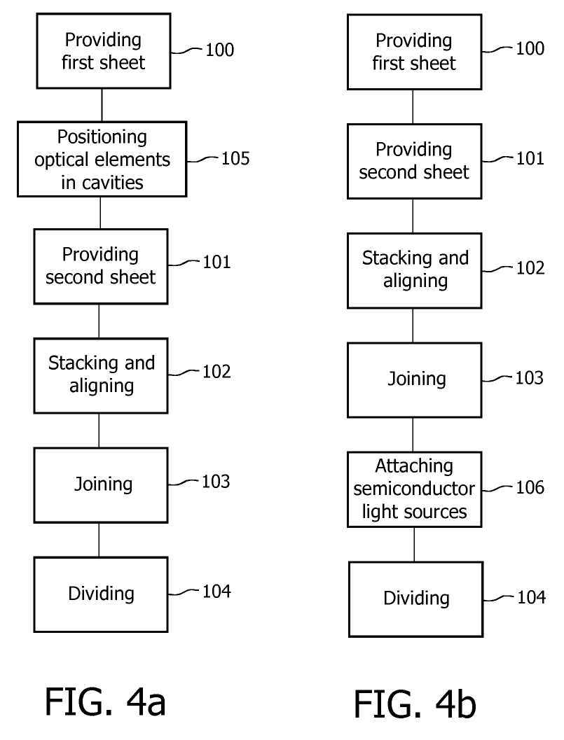

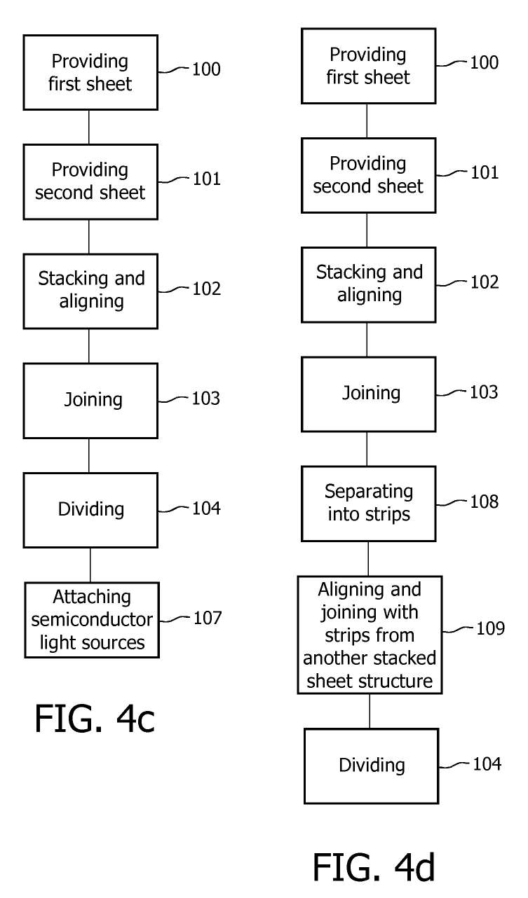

FIG. 4a is a flow chart illustrating a first embodiment of the manufacturing method in FIG. 3.

FIG. 4b is a flow chart illustrating a second embodiment of the manufacturing method in FIG. 3.

FIG. 4c is a flow chart illustrating a third embodiment of the manufacturing method in FIG. 3.

FIG. 4d is a flow chart illustrating a fourth embodiment of the manufacturing method in FIG. 3.

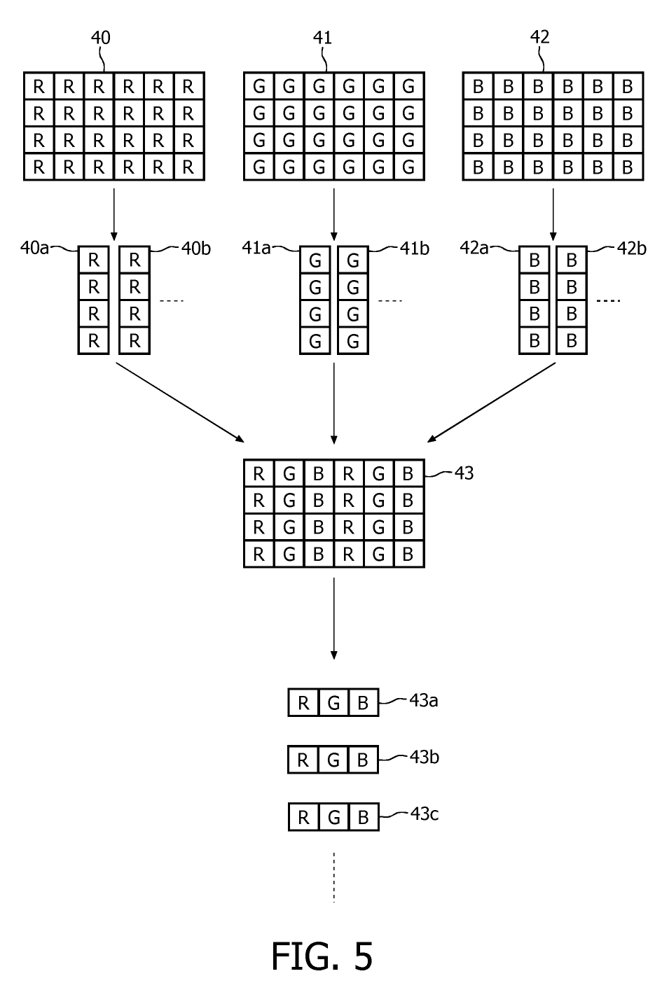

FIG. 5 is a schematic illustration of an exemplary production flow according to the manufacturing method in FIG. 4d.

In the following description, the present invention is described with reference to a VCSEL (Vertical Cavity Surface Emitting Laser) based light emitting module for achieving emission of white light. It should be noted that this by no means limits the scope of the invention, which is equally applicable to light emitting modules, which are based on other semiconductor light sources, such as various types of LEDs and other types of semiconductor lasers, such as edge emitting lasers. Furthermore, other forms of light modification than those described in the present description may be desirable depending on application and type of semiconductor light source. Additionally, it should be noted that the light emitting module need not necessarily be adapted to emit white light, but may be configured to emit light of practically any color or of variable colors. Furthermore, although the semiconductor lasers described below emit light having approximately double the desired wavelength, one or more of the desired colors may well be generated directly from the semiconductor light source. In this case, the optical elements comprised in the light-modifying member would essentially be astigmatic lenses or light-collimating lenses which modify the emitted beam(s) in order to achieve round beam shapes. Thereby, the functionality of beam shaping is achieved by one sheet portion comprised in the stacked sheet element.

FIG. 1 is a schematic illustration of an exemplary lighting device according to the present invention.

In FIG. 1, a lighting device, in the form of a projector 1 for connection to a computer 2 is shown. In the projector 1, a lamp 3 is provided, having a laser-based light emitting module 4 and first beam-modifying optics 5. After passing through the first beam-modifying optics 5, the light from the light emitting module 4 passes through an SLM- module (Spatial Light Modulator) 6 and second beam-modifying optics 7 to project an image determined by the SLM-module 6. The lamp 3 and the SLM-module 6 are controlled by an internal controller 8, which is configured to receive instructions from the computer 2, via a communication interface 9. The lamp 3 and the controller 8 are powered via an internal power supply 10, which receives AC-power through a power cord 11.

FIGS. 2a-b show a preferred embodiment of a light emitting module 19 according to the present invention.

In FIGS. 2a-b, three semiconductor light source modules in the form of VCSELs 20a-c (FIG. 2b) are shown to be joined to a light-modifying member 21, which is positioned with respect to the VCSELs 20a-c in a direction of emission of light by the VCSELs 20a-c. The VCSELs 20a-c are typically capable of emitting light having principal wavelengths in the ranges of 1220-1300 nm (610-650 nm), 1020-1080 nm (510-540 nm), and 840-960 nm (420-480 nm), respectively, where the wavelength ranges obtained after frequency doubling are given within parentheses (these are also the preferred wavelength ranges in the above-mentioned alternative embodiment of having semiconductor light sources directly capable of emitting such light). Each VCSEL 20a-c is die bonded to a respective silicon sub-mount 22a-c and wire-bonded to a respective lead frame 23a-c, which is also attached to the respective sub-mount 22a-c. On the opposite side of the sub-mounts 22a-c, a heat sink in the form of a metal slab 24 with cooling fins is arranged.

Lead frame pads 25a-b (for simplicity of drawing, only two such pads are indicated here) are connected to corresponding pads 26a-b on the bottom side of the lowest, here referred to as first, sheet portion 27 comprised in the light-modifying member 21. Following connection of the VCSEL-modules 20a-c to the light-modifying member 21, the VCSELs are encapsulated with transparent underfill in order to achieve environmental protection of the VCSELs 20a-c and the bond wires. Having been separated from an integral stacked sheet structure, the light-modifying member 21 is constituted by six sheet portions, each contributing with its own functionality to the light-modifying member 21. Depending on functionality, the different sheets (and consequently sheet portions) may be made of different materials. Such different materials are preferably matched with respect to thermal expansion properties. Alternatively, a stress-absorbing transition layer may be provided between sheets that are not matched with respect to thermal expansion properties. For sheets, that are intended to provide electrical connection paths and/or support electric components, conventional circuit board materials, such as FR-4, are preferred. These sheets may, of course, perform the added functionality of supporting and positioning optical elements. For a sheet intended for supporting optical elements, the sheet thickness may be determined by the optical elements. In some cases, a sheet thickness may be several millimeters. Other sheets are advantageously made of glass or other, more or less, homogeneous materials. In the first sheet portion 27, first optical elements in the form of slanted dichroic mirrors 28a-c are embedded for reflecting IR-light out of the light emitting module 19 and for selecting a polarization direction. In the second sheet portion 29, second optical elements in the form of frequency doubling crystals 30a-c (FIG. 2b) are embedded in cavities formed in the second sheet portion 29. The second sheet portion 29 further includes circuitry for enabling control of the light emitting module 19, the circuitry here being provided in the form of heaters 31a-c (FIG. 2b) for heating the frequency doubling crystals 30a-c. The third sheet portion 32 is a transparent cover for protecting the underlying frequency doubling crystals or for thermal insulation of the heated frequency doublers from their environment. Such thermal insulation may also be provided, for example in the form of additional stacked sheet portions, between the first 27 and second 29 sheet portions. As a fourth sheet portion 33, a (narrow) wavelength selective mirror or Bragg-grating is provided. The purpose of the Bragg-grating 33 is to form an end mirror in the extended cavity formed by the light-modifying member 21. Through the Bragg-grating 33, red R, green G, and blue B light originally emanating from the VCSELs 20a-c, respectively, enters the fifth sheet portion 34, in which semitransparent outcoupling mirrors 35a-c are embedded to direct and mix light so that a beam 36 of thus combined, white light may be emitted from the light emitting module 19. Finally, a sixth sheet portion 37 protects the outcoupling mirrors 35a-c.

The outcoupling module constituted by the fifth 34 and sixth 37 sheet portions is optional depending on application. In the application shown in FIG. 1, the light emitting module may be used with or without this outcoupling module.

The above-mentioned connection between the semiconductor light sources and the light-modifying member is preferably achieved through soldering or welding, or, according to an alternative embodiment, the lowest sheet portion may be adapted to receive the semiconductor light source modules, for example, through sliding, and the connection may then be achieved through pressing against each other of corresponding contact pads provided on the semiconductor light source module and the lowest sheet portion, respectively.

In the following, the manufacturing method according to the present invention will be described with reference to FIG. 3 and FIGS. 4a-d, where FIGS. 4a-d illustrate various embodiments of the method in FIG. 3.

With reference now to FIG. 3, a first sheet is provided in a first step 100. In a subsequent step 101, a second sheet is provided. Thereafter, in step 102, the first and second sheets are stacked and aligned. The stacked and aligned sheets are, in a following step 103, joined to each other. Following joining, or lamination, the resulting integral stacked sheet structure is, in step 104, divided, or singularized, into individual stacked sheet elements.

According to a first embodiment of the manufacturing method of the invention, as illustrated in FIG. 4a, the additional step 105 of placing optical elements in cavities provided in the first sheet may preferably be inserted between steps 100 and 101 in FIG. 3.

According to a second embodiment of the manufacturing method of the invention, as illustrated in FIG. 4b, the additional step 106 of attaching semiconductor light sources to the integral stacked sheet structure may preferably be inserted between steps 103 and 104 in FIG. 3.

According to a third embodiment of the manufacturing method of the invention, as illustrated in FIG. 4c, the additional step 107 of attaching semiconductor light sources to singularized stacked sheet elements may preferably be inserted following step 104 in FIG. 3. For example, the semiconductor light sources may be pre-fixed to a heat sink and/or other carrier and the stacked sheet elements attached to these pre-fixed semiconductor light sources.

According to a fourth embodiment of the manufacturing method of the invention, as illustrated in FIG. 4d, the additional steps 108 and 109 of separating the integral stacked sheet structure into first stacked sheet strips, and aligning and joining side-by-side the first stacked sheet strips and second stacked sheet strips originating from another stacked sheet structure, such that a compound stacked sheet structure is formed, are performed prior to step 104 in FIG. 3. Of course, each of the above second and third embodiments may advantageously be combined with the above first embodiment. Furthermore, the above fourth embodiment may advantageously be combined with any one of the above first, second and third embodiments.

The above-mentioned fourth embodiment will now be described in greater detail with reference to FIG. 5 which schematically illustrates a part of an exemplifying production flow according to the fourth embodiment of the manufacturing method according to the present invention.

In FIG. 5, stacked sheet structures 40, 41, 42 are provided, which are each adapted for a different color, here illustrated by R (for red), G (for green) and B (for blue), respectively. Each of the stacked sheet structures 40, 41, 42 are, as described above, separated into stacked sheet strips 40a-b, 41a-b, 42a-b (for ease of drawing only two of each are illustrated). These stacked sheet strips 40a-b, 41a-b, 42a-b are subsequently aligned and joined side-by-side so that a compound stacked sheet structure 43 is formed. According to the present example, the stacked sheet strips are aligned and joined in the following order: 40a, 41a, 42a, 40b, 41b, 42b, . . . in order to form RGB-structures. After the aligning and joining, the compound stacked sheet structure 43 is divided into stacked sheet elements 43a-c (for ease of drawing only three of these are illustrated) which are adapted for RGB-operation. These stacked sheet elements may be RGB-type light emitting modules, or light-modifying members adapted for use in such light emitting modules.

The person skilled in the art realises that the present invention by no means is limited to the preferred embodiments described above. On the contrary, many modifications and variations are possible within the scope of the appended claims. For example, the described sub mounts may be made of any other good heat conductor, such as copper or diamond. Furthermore, the semiconductor light source may be electrically connected to the light-modifying member by any means, such as via a conductor pattern formed directly on the sub mount. The here described wire bonding may also be substituted by any alternative bonding technique known in the art, such as flip-chip. Additionally, the heat sink may be passive, as shown herein, or active. An active heat sink may utilize, for example, a fan or a peltier element. The herein described single VCSELs may, of course, advantageously be replaced by arrays of VCSELs emitting light at each principal wavelength. Furthermore, the spatial light modulator in the described exemplary lighting device may be replaced by a corresponding modulator implemented in a sheet portion of the light emitting module. In the embodiment herein described, the light emitting module has three semiconductor light sources in order to achieve emission of white light. To this end, a larger number and other colors of light-sources than those described above may be used. Especially for general purpose lighting applications, it may be useful to add a fourth or even a fifth color, such as amber or cyan, which improves the color rendering index.

1. A light emitting module (19), comprising:
at least one semiconductor light source (20a-c) capable of emitting light; and
a light-modifying member (21) arranged adjacent to said at least one semiconductor light source (20a-c) in a direction of emission of said light,
characterized in that said light-modifying member (21) is formed by a stacked sheet element (21) separated from an integral stacked sheet structure comprising first and second stacked sheets, so that said stacked sheet element (21) includes first and second sheet portions of said first and second stacked sheets, and
wherein at least said first sheet portion is configured to modify said emitted light.

2. A light emitting module (19) according to claim 1, wherein said second sheet portion is configured to modify said emitted light.

3. A light emitting module (19) according to claim 1, wherein at least one of said sheet portions contains at least one optical element (28a-c, 30a-c, 35a-c).

4. A light emitting module (19) according to claim 3, wherein the light-modifying member (21) is arranged such that said at least one optical element (28a-c, 30a-c, 35a-c) is aligned with said at least one semiconductor light source (20a-c).

5. A light emitting module (19) according to claim 3, comprising a plurality of semiconductor light sources (20a-c), and at least a first corresponding plurality of optical elements (28a-c; 30a-c; 35a-c) contained in said at least one sheet portion (27; 29; 34).

6. A light emitting module (19) according to claim 3, wherein said at least one optical element (28a-c; 30a-c; 35a-c) is embedded in a corresponding cavity in said sheet portion (27; 29; 34).

7. A light emitting module (19) according to claim 1, wherein said light-modifying member (21) further includes a third sheet portion of a third stacked sheet comprised in said integral stack structure.

8. A light emitting module (19) according to claim 1, wherein at least one of said sheet portions (29) includes circuitry (31a-c) for enabling control of said light emitting module (19).

9. A light emitting module (19) according to claim 1, wherein said light-modifying member (21) comprises connecting means for connecting the light emitting module (19) to external control circuitry.

10. A light emitting module (19) according to claim 1, comprising:
a first semiconductor light source capable of emitting light having a first wavelength distribution; and
a second semiconductor light source capable of emitting light having a second wavelength distribution,
wherein said light emitting module (19) is capable of emitting light having a third wavelength distribution achieved through combining light emitted by at least said first and second semiconductor light sources.

11. A light emitting module (19) according to claim 1, comprising:
a first semiconductor light source (20a) capable of emitting light having a first wavelength distribution;
a second semiconductor light source (20b) capable of emitting light having a second wavelength distribution;
a third semiconductor light source (20c) capable of emitting light having a third wavelength distribution; and
a light-modifying member (21), including:
a first sheet portion (29) having at least three cavities each containing an optical element (30a-c); and
a second sheet portion (32) configured to cover the cavities in the first sheet portion (29), thereby protecting said optical elements (30a-c),
wherein each of said semiconductor light sources (20a-c) is arranged in a position where said light source is aligned to a corresponding optical element (30a-c), and joined to said light-modifying member (21) at that position.

12. A light emitting module (19) according to claim 10, wherein at least one of said semiconductor light sources (20a-c) is an array of laser diodes or LEDs.

13. A lighting device (1), comprising:
a light emitting module (19) according to claim 1;
control circuitry (8) configured to control said light emitting module (19); and
a power supply (10) configured to supply power to said light emitting module (19).

14. A method for manufacturing a stacked sheet element (19, 21), comprising the steps of:
providing (100) a first sheet configured to modify light emitted by a semiconductor light source;
providing (101) a second sheet;
stacking and aligning (102) said first and second sheets; and
joining (103) said first and second sheets, thereby forming an integral stacked sheet structure; and
dividing (104) said integral stacked sheet structure, thereby forming a plurality of stacked sheet elements (19, 21), each including a first sheet portion and a second sheet portion.

15. A method according to claim 14, wherein said step (100) of providing a first sheet comprises the steps of:
providing (100) a first sheet having at least a first plurality of cavities, each of which cavities being adapted to receive a first optical element; and
positioning (105) first optical elements in corresponding cavities.

16. A method according to claim 14, wherein said stacked sheet elements are strip shaped, further comprising:
aligning and joining (109) side-by-side first strip shaped stacked sheet elements divided from a first stacked sheet structure, and second strip shaped stacked sheet elements divided from a second stacked sheet structure, thereby forming a compound integral stacked sheet structure, said compound structure comprising first and second stacked sheet elements, and
dividing said compound stacked sheet structure into a plurality of compound stacked sheet elements, such that each compound stacked sheet element includes portions of both said first and second stacked sheet elements.

17. The method according to claim 16, wherein said compound stacked sheet is divided across the lengthwise orientation of said strip shaped elements.

18. The method according to claim 16, said compound stacked sheet structure comprising strip shaped stack sheet elements from three different stacked sheet structures.

19. A method according to claim 14, further comprising the step of:
providing each of said stacked sheet elements, or each of said compound stacked sheet elements, with at least one semiconductor light source, thereby forming a plurality of light emitting modules.

20. A method according to claim 19, wherein the step of providing the stacked sheet elements with a semiconductor light source comprises the step of:
attaching (106) a plurality of semiconductor light sources to said integral stacked sheet structure, so that at least one semiconductor light source is provided to each of said stacked sheet elements.

21. A method according to claim 19, wherein the step of providing the stacked sheet elements with a semiconductor light source comprises the step of:
attaching (107) at least one semiconductor light-source to each of said stacked sheet elements following division (104).
